(19) United States
(12) Patent Application Publication
(10) Pub. No.: US 2003/0194622 A1
(43) Pub. Date: Oct. 16, 2003

(54) Exposure lens, method of manufacturing color picture tube and exposure device

(75) Inventor: Kumao Ichinose, Nagaokakyo-shi (JP)

Correspondence Address: MERCHANT & GOULD PC, P.O. BOX 2903, MINNEAPOLIS, MN, 55402-0903, US

(73) Assignee: Matsushita Electric industrial Co., Ltd., Kadoma-shi (JP)

(21) Appl. No.: 10/408,873

(22) Filed: Apr. 8, 2003

(30) Foreign Application Priority Data
Apr. 12, 2002 (JP) 2002-110155

(51) Int. Cl. G03F 7/24; G03B 27/58; G03B 27/62; G02B 13/18; G02B 3/02; G03B 27/54

(52) U.S. Cl. 430/23; 355/47; 355/67; 359/708

(57) ABSTRACT

After forming a phosphor film on an inner face of a front panel, light exposure is performed with respect to the phosphor film by irradiating light from an exposure light source onto the phosphor film through an exposure lens. The exposure lens has a concave incidence surface on which light from the exposure light source is incident, and the incidence surface has an average radius of curvature of 100 mm to 500 mm. Thus, light to which peripheral portions are exposed can have a smaller incident angle with respect to the incidence surface of the exposure lens, thereby allowing the reflectance of the light to be decreased. As a result, even in light exposure with respect to a phosphor film of a color picture tube with a wide deflection angle, an amount of light for the light exposure can be secured in the peripheral portions.

### BACKGROUND OF THE INVENTION

1. Field of the Invention

The present invention relates to an exposure lens and an exposure device that are used to form a phosphor screen of a color picture tube and a method of manufacturing a color picture tube using the exposure lens.

2. Related Background Art

FIG. 3 is a schematic view in cross section along a diagonal line of a phosphor screen, showing a color picture tube in common use. As shown in FIG. 3, a phosphor screen 4 is formed on an inner face of a front panel 1, and a color selecting shadow mask 2 is attached to an inner side of the front panel 1 so as to be opposed to the phosphor screen 4. Electron beams 5 emitted from an electron gun 3 pass through apertures of the shadow mask 2 to be irradiated respectively in predetermined positions on the phosphor screen 4, thereby allowing the phosphors to emit light. The electron beams 5 are deflected respectively at an angle in a range of angles defined by a deflection angle 6. An angle obtained by halving the deflection angle 6 is indicated as a deflection half angle 7. The phosphor screen 4 is formed by a light-exposing step in which after a phosphor film is formed on the inner face of the front panel by, for example, applying a phosphor liquid, light from an exposure light source is irradiated onto the phosphor film through an exposure lens.

FIG. 4 is a partially expanded sectional side view of the phosphor screen 4. A plurality of trios of red-, green- and blue-emitting phosphor dots or stripes are arranged alternately to form the phosphor screen 4. If the phosphor dots are arranged respectively in predetermined positions with accuracy, the electron beams 5 that have passed through the apertures of the shadow mask 2 impinge respectively on the predetermined phosphor dots. However, if the phosphor dots are arranged with insufficient positional accuracy, so-called mislanding is caused. That is, light is emitted not from the entire surface of each phosphor dot but from a portion thereof, thereby causing a luminance drop, and each of the electron beams 5 impinges on the phosphor dot of a different color adjacent to the phosphor dot of a corresponding color. In order for the electron beams 5 to allow the predetermined phosphors to emit light appropriately, it is required that the phosphor dots be arranged with accuracy respectively in positions on the inner face of the front panel 1, on which the electron beams 5 land. In order to arrange the phosphor dots with positional accuracy, when performing light exposure with respect to the phosphor screen, the trajectories of light beams are corrected using an optical lens.

FIG. 5 is a simplified sectional view of an optical system of an exposure device that is used to perform light exposure with respect to a phosphor screen. An exposure light source 21 is a linear lamp that emits ultraviolet beams. A small-sized auxiliary lens 22 is provided as a next stage to the exposure light source 21 and adjusts the trajectories of light beams 51 according mainly to an azimuth angle. An exposure lens (main lens) 23 is used to correct the trajectories of the light beams 51 so that an optimum correction can be performed with respect to the entire surface of the phosphor screen. The exposure lens 23 has a flat incidence surface on which light from the exposure light source 21 is incident and a non-spherical emitting surface from which the light is emitted. A light amount correction filter 24 functions to adjust light amounts so that phosphors can be adjusted in size. The light beams 51 whose trajectories have been corrected pass through apertures of a shadow mask 2 and land respectively in predetermined positions on an inner face of a front panel 1, so that phosphors in the positions are exposed to the light beams 51. Each of light beams to which the outermost periphery of the phosphor screen is exposed and a normal (tube axis) passing through the center of the phosphor screen form a deflection half angle 7.

A distance from the center of the exposure light source 21 to an end face of a side face portion of the front panel 1 is referred to as a L value 40. The L value 40 has a value of, for example, 170 to 310 mm in the case of a 86 cm color picture tube, and about 150 to 270 mm in the case of a 76 cm color picture tube.

For obtaining thinner color picture tubes, it has been requested to increase the deflection angle so that color picture tubes can be reduced in the depth dimension. With the deflection angle increased, when light exposure is performed with respect to a phosphor screen using the above-mentioned conventional exposure device, a sufficient amount of light for the light exposure cannot be provided in peripheral portions of the phosphor screen, which has been disadvantageous.

For example, with the deflection angle increased from 102° to 120°, when light exposure is performed, while an amount of light obtained in a central portion of the phosphor screen is increased by about 20%, an amount of light obtained in the peripheral portions of the phosphor screen is decreased by about 40%, resulting in a larger difference between the light amounts. The amount of light obtained in the central portion of the phosphor screen is increased because a distance from a light source to the phosphor screen is made smaller. The amount of light obtained in the peripheral portions of the phosphor screen is decreased because light beams directed to the peripheral portions have a larger incident angle relative to a normal of the incidence surface of the exposure lens, thereby increasing an amount of light reflected from the incidence surface of the exposure lens.

FIG. 6 is a graph showing the results of a simulation performed to determine how an incident angle of a light beam used for light exposure affects a reflectance in the case of using an exposure lens whose incidence surface is flat as in the conventional exposure lens. The incident angle on the lateral axis of the graph is defined as an angle formed by a normal of the exposure lens and an incident light beam. The reflectance on the vertical axis is obtained by dividing an amount of reflected light beams by an amount of incident light beams. For example, in the case of a color picture tube with a deflection angle of 102°, an incident angle of a light beam incident on the outermost periphery of a phosphor screen corresponds to a deflection half angle (half of the deflection angle) of 51°, and in this case, a reflectance of about 12% is found from the graph shown in FIG. 6. With the deflection angle set to 120°, that is, with the incident angle set to 60°, the reflectance is increased to about 19%.

As a means for preventing this reflection, a technique is known in which a non-reflective coating is applied on a surface of an exposure lens. However, since the non-reflective coating has a uniform thickness, while the reflectance can be set to be optimum in a central portion of the exposure lens, the effect of the non-reflective coating hardly can be attained in peripheral portions of the exposure lens, on which light beams are incident diagonally.

### SUMMARY OF THE INVENTION

With the foregoing in mind, the present invention has as its object to solve the above-mentioned problem with the conventional exposure lens and reduce the reflection of incident light from an entire area of an incidence surface of an exposure lens so that when light exposure is performed with respect to a phosphor screen of a color picture tube, a sufficient amount of light for the light exposure can be secured even in peripheral portions of the phosphor screen, thereby allowing an excellent phosphor screen surface to be provided.

An exposure lens according to the present invention is an exposure lens that is used for light exposure with respect to a phosphor screen of a color picture tube. The exposure lens has a concave incidence surface on which light from an exposure light source is incident, and the incidence surface has an average radius of curvature of 100 mm to 500 mm.

Furthermore, a method of manufacturing a color picture tube according to the present invention includes a light-exposing step of performing light exposure with respect to a phosphor film, in which after the phosphor film is formed on an inner face of a front panel, light from an exposure light source is irradiated onto the phosphor film through an exposure lens. The exposure lens has a concave incidence surface on which light from the exposure light source is incident, and the incidence surface has an average radius of curvature of 100 mm to 500 mm.

Moreover, an exposure device according to the present invention is an exposure device that is used to perform light exposure with respect to a phosphor screen of a color picture tube. The exposure device includes an exposure light source, an auxiliary lens that adjusts trajectories of light beams from the exposure light source, a main lens on which light emitted from the auxiliary lens is incident, and a light amount correction filter on which light emitted from the main lens is incident and that adjusts an amount of light to be emitted. In the exposure device, the main lens has a concave incidence surface on which light from the exposure light source is incident, and the incidence surface has an average radius of curvature of 100 mm to 500 mm.

### BRIEF DESCRIPTION OF THE DRAWINGS

FIG. 1 is a cross sectional view of an exposure lens according to Embodiment 1 of the present invention.

FIG. 2 is a cross sectional view of an exposure lens according to Embodiment 2 of the present invention.

FIG. 3 is a sectional view along a diagonal line of a phosphor screen, showing a color picture tube.

FIG. 4 is a partially expanded sectional side view of a phosphor screen.

FIG. 5 is a schematic sectional view showing an optical system of a conventional exposure device.

FIG. 6 is a diagram showing the relationship between an incident angle of a light beam and a reflectance with regard to a conventional main lens with a flat incidence surface.

FIG. 7A is a diagram showing the relationship between an inclination of the incidence surface and each of an incident light beam and a reflected light beam with regard to the conventional main lens.

FIG. 7B is a diagram showing the relationship between an inclination of an incidence surface and each of an incident light beam and a reflected light beam with regard to a main lens according to Embodiment 1 of the present invention.

FIG. 8 is a graph showing the relationship between a radius of curvature and a reflectance of a main lens.

### DETAILED DESCRIPTION OF THE INVENTION

The incidence surface of the exposure lens is formed of a concave curved surface, thereby attaining a smaller angle formed by an incident light beam and a normal of the incidence surface. For example, in the case of a color picture tube with a deflection angle of 120°, by the use of an exposure lens with a concave incidence surface having a radius of curvature of 500 mm in place of the conventional exposure lens with a flat incidence surface, an angle formed by an incident light beam and a normal of the incidence surface of the lens can be decreased from 60° to 54°. As a result, the reflectance on the incidence surface of the lens can be decreased from 19% to 14%, and thus a sufficient amount of light can be secured at peripheral portions of a phosphor screen.

With an average radius of curvature of less than 100 mm, a difference in the effect of decreasing the reflectance becomes insignificant. Further, the problem of lowered processing accuracy also may be caused due to the shape of a steeper concave curve. Thus, preferably, the average radius of curvature is not less than 100 mm.

Herein, the “average radius of curvature” is defined as a radius of a circle that has a center on a normal passing through a central point of an exposure lens and is drawn by passing through two points, which are the central point and a point in a peripheral portion (position in which a light beam is incident that is emitted from an exposure light source in a direction defined by a deflection half angle) of the exposure lens. Where a distance in a plane direction from the central point to the point in the peripheral portion is indicated as r, and a difference in a height direction between these two points is indicated as z, the average radius of curvature can be determined using an expression (r²+z²)/(2×z). In the case of an exposure lens with a non-spherical incidence surface, the average radius of curvature can be determined as a radius of an imaginary spherical surface passing through the two points, i.e. a central point and a point in a peripheral portion of the exposure lens.

Furthermore, in the conventional exposure lens with a flat incidence surface, an emitting surface has been of a concave surface having a small radius of curvature. In contrast to this, according to the present invention, an exposure lens has an incidence surface formed of a concave curved surface, thereby allowing an emitting surface to have the shape of a more gentle concave curve than in the conventional exposure lens. Thus, an emitting surface of an exposure lens can be manufactured with improved processing accuracy, thereby allowing mislanding to be corrected with higher accuracy. Further, an emitting surface also can be configured so as to have a convex shape.

Furthermore, preferably, in the exposure lens according to the present invention, portions of the incidence surface, on which light beams emitted from the exposure light source in directions defined by a deflection half angle of the color picture tube are incident, have a radius of curvature of 100 mm to 500 mm and a reflectance of 14% or lower.

According to this preferred configuration, a sufficient light amount also can be secured with respect to light emitted from an exposure lens in directions defined by a deflection half angle of a color picture tube relative to a center axis of the exposure lens, i.e. light landing at the outermost periphery in an exposure area on a phosphor screen surface. For example, with a deflection angle of 120°, at least portions of an incident surface on which light emitted in directions defined by an angle of 60° relative to a center axis of an exposure lens is incident should have a radius of curvature of 100 mm to 500 mm. Other portions of the incident surface on an inner side (central side) of the respective positions of the portions may have a radius of curvature of not less than 500 mm.

Furthermore, preferably, the exposure lens according to the present invention is formed of a material having a refractive index of 1.4 to 1.6.

Furthermore, preferably, the incidence surface of the exposure lens according to the present invention is a non-spherical surface.

Furthermore, a method of manufacturing a color picture tube according to the present invention includes a light-exposing step of performing light exposure with respect to a phosphor film, in which after the phosphor film is formed on an inner face of a front panel, light from an exposure light source is irradiated onto the phosphor film through an exposure lens. The exposure lens has a concave incidence surface on which light from the exposure light source is incident, and the incidence surface has an average radius of curvature of 100 mm to 500 mm.

According to the manufacturing method of the present invention, an incidence surface of an exposure lens is formed of a concave curved surface, thereby attaining a smaller angle formed by an incident light beam and a normal of the incidence surface. Thus, the reflectance on the incidence surface of the lens can be decreased, so that a sufficient amount of light can be secured in peripheral portions of a phosphor screen.

Furthermore, in the manufacturing method according to the present invention, preferably, in the exposure lens, portions of the incidence surface, on which light beams emitted from the exposure light source in directions defined by a deflection half angle of a color picture tube are incident, have a radius of curvature of 100 mm to 500 mm and a reflectance of 14% or lower. Further, preferably, the exposure lens is formed of a material having a refractive index of 1.4 to 1.6. Further, preferably, the incidence surface of the exposure lens is a non-spherical surface.

Moreover, the exposure device according to the present invention has the same basic configuration as that of the conventional exposure device shown in FIG. 5. That is, the exposure device according to the present invention is an exposure device that is used to perform light exposure with respect to a phosphor screen of a color picture tube. The exposure device includes an exposure light source, an auxiliary lens that adjusts trajectories of light beams from the exposure light source, a main lens on which light emitted from the auxiliary lens is incident, and a light amount correction filter on which light emitted from the main lens is incident and that adjusts an amount of light to be emitted. Herein, in the exposure device according to the present invention, the main lens has a concave incidence surface on which light from the exposure light source is incident, and the incidence surface has an average radius of curvature of 100 mm to 500 mm.

Hereinafter, the exposure lens (in the following description, referred to as a main lens) according to the present invention will be described with reference to the appended drawings. In the description, an exposure lens used for light exposure with respect to a phosphor screen of a 86 cm color picture tube with a deflection angle of 120° is used as an example.

(Embodiment 1)

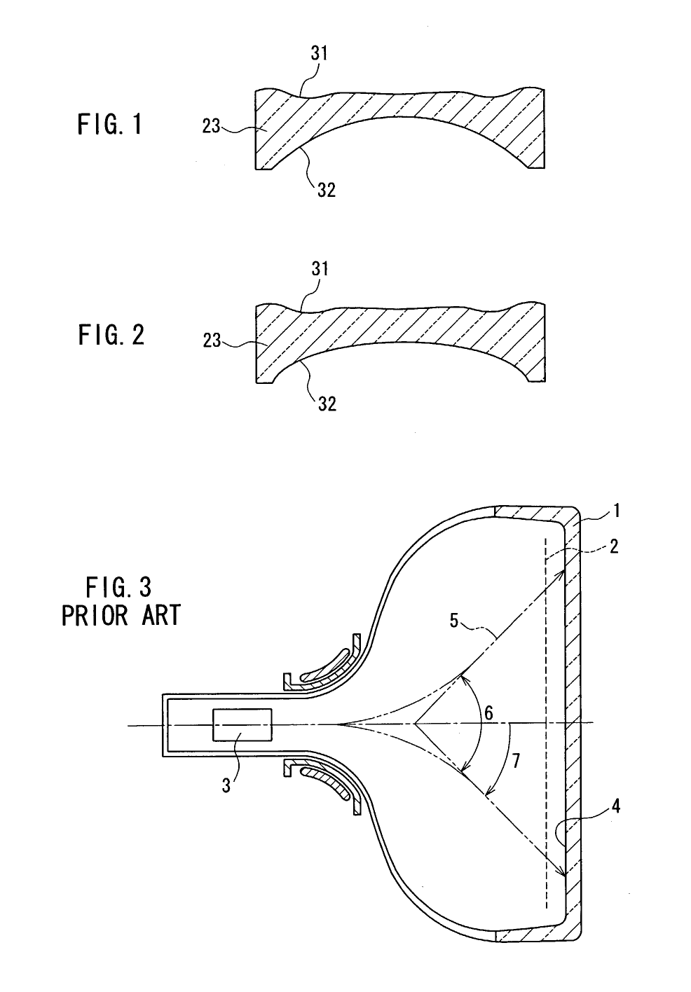

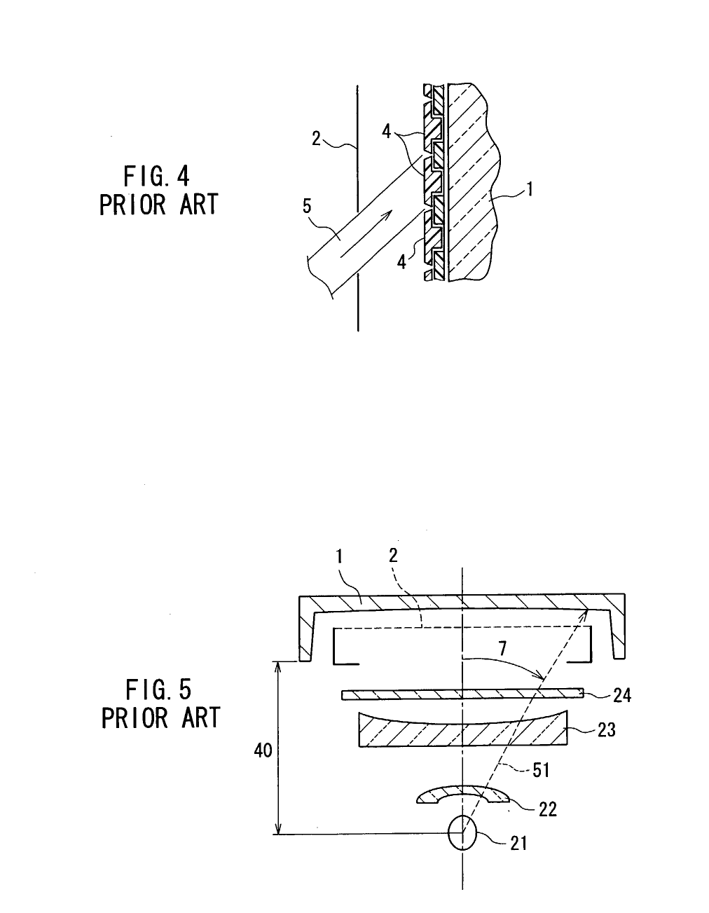

FIG. 1 is a cross sectional view of a main lens according to Embodiment 1 of the present invention. An incidence surface 32 of a main lens 23 is a simple curved surface formed of a portion cut from a spherical surface having a radius of curvature of 300 mm. This configuration allows the incidence surface 32 of the main lens 23 to have an inclination. With the radius of curvature set to 300 mm, an inclination of about 13° can be provided with respect to a central point of the main lens 23 at a distance of 70 mm from the central point.

An emitting surface 31 of the main lens 23 is a non-spherical surface having an average radius of curvature of 10,000 mm. The main lens 23 may be formed of a material having a refractive index of 1.4 to 1.6.

The description is directed next to the function and effect of reducing reflection on the incidence surface 32.

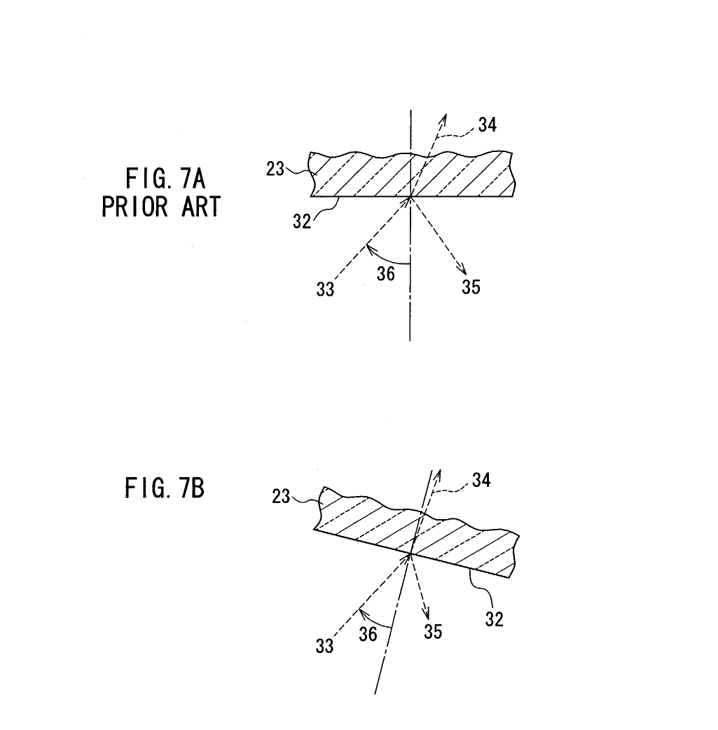

FIGS. 7A and 7B show the relationship between an incident angle 36 and each of an incident light beam 33 and a reflected light beam 35 on the incidence surface 32 of the main lens 23. FIG. 7A shows a conventional main lens with a flat incidence surface, and FIG. 7B shows the main lens according to the present invention having an inclined incidence surface. In each of the figures, alternate long and short dashed lines indicate a normal of the incidence surface. In light exposure performed for a color picture tube with a deflection angle of 120° using the conventional main lens 23 shown in FIG. 7A, generally, each of light beams directed to peripheral portions of a phosphor screen is incident on the incidence surface 32 of the main lens 23 at an angle of 60° as the incidence angle 36 relative to the normal of the incidence surface. While a major portion of the incident light beam 33 is transmitted as an emitting light beam 34, a portion of the incidence light beam 33 is not transmitted through the main lens 23 but reflected therefrom to be turned into the reflected light beam 35. The reflectance of the incidence surface 32 varies according to the refractive index of a material of the main lens 23 and an angle formed by the incident light beam 33 and the normal of the incidence surface.

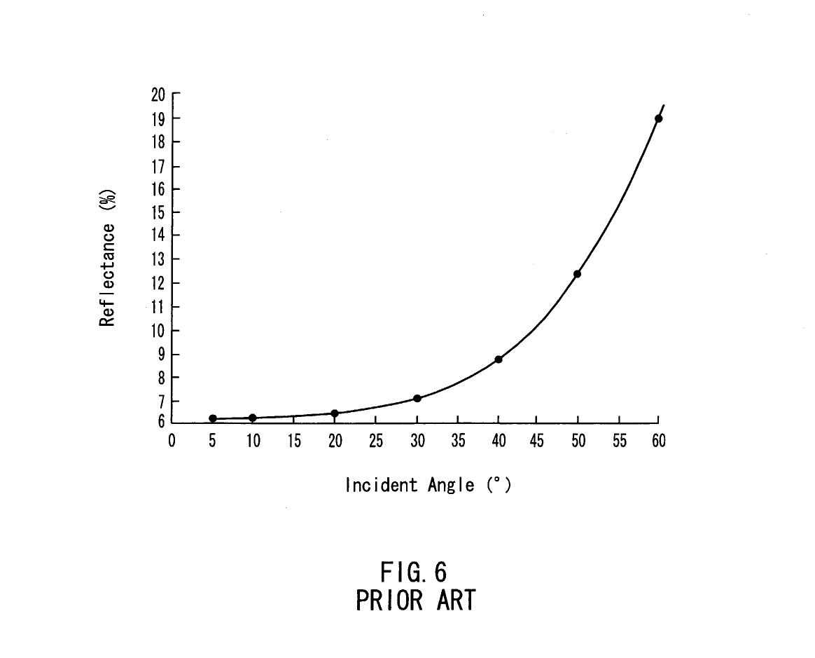

With the radius of curvature of the incidence surface of the main lens set to 300 mm, as shown in FIG. 7B, the incidence surface at positions in which light beams traveling toward peripheral portions of a phosphor screen, i.e. light beams traveling toward directions defined by a deflection half angle, are incident has an inclination of about 13° (0° in the case of the conventional main lens). According to this configuration, an angle formed by an incident light beam and the normal of the incidence surface can be decreased to 470 from an angle of 60° obtained in the case of the conventional main lens. As shown in FIG. 6, the reflectance in the respective positions also can be decreased to about 11% from a reflectance of 19% obtained in the case of the conventional main lens.

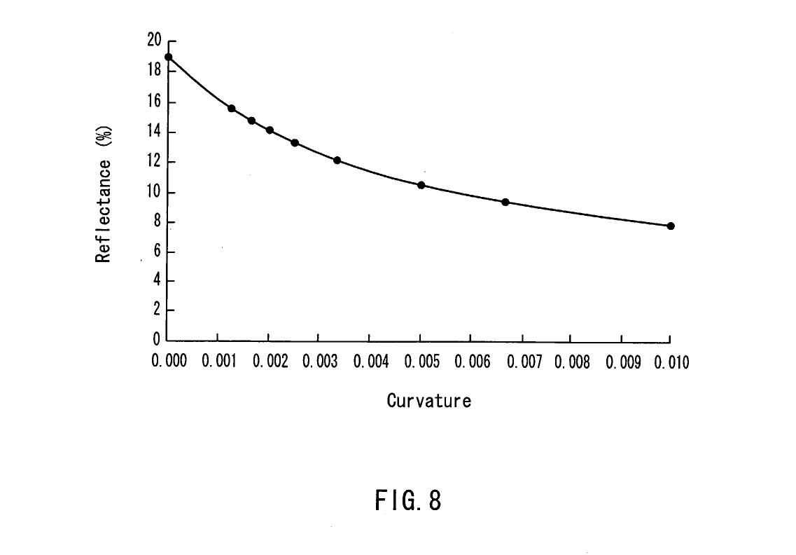

FIG. 8 is a graph showing the results of a simulation performed to determine the respective values of the reflectance to be obtained when the radius of curvature of the incidence surface is changed in a color picture tube with a deflection angle of 120°. The reflectance values are determined as the reflectance at positions at which light beams emitted toward peripheral portions of a main lens, i.e. light beams emitted in directions defined by a deflection half angle are incident. The curvature on the lateral axis of the graph is obtained by dividing 1 by a radius of curvature (mm). As can be seen from this graph, with the curvature of the incidence surface set to 0.0033, that is, with the radius of curvature set to 300 mm, the reflectance is decreased to about 12%. There is a slight margin of errors between these values and the calculated values shown in FIG. 6.

Preferably, the incidence surface of the main lens has a concave shape having a curvature of not less than 0.002, i.e. a radius of curvature of not more than 500 mm. According to this configuration, the reflectance on the incidence surface of the lens can be decreased to 14% or lower. That is, compared with a reflectance of about 19% in the case of the conventional main lens (having a curvature of 0), the reflectance is improved by not less than 25%. Thus, a sufficient amount of light used for light exposure with respect to peripheral portions of a phosphor screen can be secured.

With an incidence surface having a radius of curvature of less than 100 mm, the effect of decreasing the reflectance does not change significantly, and the processing accuracy is lowered due to the shape of a steeper concave curve. Thus, preferably, the radius of curvature is set to not less than 100 mm.

(Embodiment 2)

FIG. 2 is a cross sectional view of a main lens 23 according to Embodiment 2 of the present invention.

This embodiment is different from Embodiment 1 described above in that the main lens 23 has a non-spherical incidence surface 32. The incidence surface 32 has a radius of curvature that is decreased in directions from a central portion to peripheral portions. The average radius of curvature of the incidence surface 32 is about 500 mm. That is, the incidence surface 32 has a radius of curvature larger than 500 mm in the central portion and a radius of curvature smaller than 500 mm in the peripheral portions. As in Embodiment 1, an emitting surface 31 is a non-spherical surface.

The main lens according to this embodiment has an average radius of curvature of 500 mm, i.e. an average curvature forming a more gentle concave curve than in Embodiment 1 (having an average radius of curvature of 300 mm). However, since the incidence surface is a non-spherical surface, the radius of curvature can be decreased to about 300 mm in the peripheral portions.

As described above, the main lens has a non-spherical incidence surface with only the peripheral portions decreased in radius of curvature, thereby allowing the incidence surface in the peripheral portions of the main lens to have a large inclination as in Embodiment 1. According to this configuration, an angle formed by each of incident light beams on the main lens that are directed to peripheral portions of a phosphor screen and a normal of the incidence surface can be decreased as in Embodiment 1. Thus, the reflectance of the incidence surface can be decreased, thereby allowing an amount of light used for light exposure to be secured.

Furthermore, the incidence surface of the main lens can be configured so as to have large inclinations only in the peripheral portions, thereby eliminating the need for a large amount of reduction in the average radius of curvature. This is advantageous in that a main lens can be processed more easily.

As described in the foregoing discussion, the present invention is effective particularly in performing light exposure with respect to a phosphor screen of a color picture tube with a wide deflection angle of about 120°. Further, the present invention is effective particularly in the case where the L value 40 shown in FIG. 5 is small, that is, a distance between the exposure light source 21 and the front panel 1 is small. For example, the present invention is effective particularly in the case of a 86 cm color picture tube having a L value of 170 to 280 mm and a 76 cm color picture tube having a L value of 150 to 250 mm.

According to the present invention, a main lens for light exposure has a concave incidence surface, which is configured as a flat surface in the conventional main lens, thereby allowing the incidence surface of the main lens to have an inclination. As a result, an angle formed by an incident light beam and a normal of the incidence surface of the main lens can be decreased. According to this configuration, the reflection on the incidence surface of the main lens can be suppressed when light exposure is performed with respect to peripheral portions of a phosphor screen. Thus, in forming a phosphor screen of a color picture tube with a wide deflection angle (for example, a deflection angle of 120°), a sufficient amount of light for light exposure can be secured, thereby allowing an excellent phosphor screen surface to be provided.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. An exposure lens that is used for light exposure with respect to a phosphor screen of a color picture tube, comprising:
a concave incidence surface on which light from an exposure light source is incident and that has an average radius of curvature of 100 mm to 500 mm.

2. The exposure lens according to claim 1,
wherein portions of the incidence surface, on which light beams emitted from the exposure light source in directions defined by a deflection half angle of the color picture tube are incident, have a radius of curvature of 100 mm to 500 mm and a reflectance of 14% or lower.

3. The exposure lens according to claim 1, wherein the exposure lens has a refractive index of 1.4 to 1.6.

4. The exposure lens according to claim 1, wherein the incidence surface is a non-spherical surface.

5. A method of manufacturing a color picture tube, comprising the step of performing light exposure with respect to a phosphor film, in which after the phosphor film is formed on an inner face of a front panel, light from an exposure light source is irradiated onto the phosphor film through an exposure lens,
wherein the exposure lens has a concave incidence surface on which light from the exposure light source is incident and that has an average radius of curvature of 100 mm to 500 mm.

6. An exposure device that is used to perform light exposure with respect to a phosphor screen of a color picture tube, comprising:
an exposure light source;
an auxiliary lens that adjusts trajectories of light beams from the exposure light source;
a main lens on which light emitted from the auxiliary lens is incident; and
a light amount correction filter on which light emitted from the main lens is incident and that adjusts an amount of light to be emitted,
wherein the main lens has a concave incidence surface on which light from the exposure light source is incident, and the incidence surface has an average radius of curvature of 100 mm to 500 mm.

7. The exposure device according to claim 6,
wherein portions of the incidence surface, on which light beams emitted from the exposure light source in directions defined by a deflection half angle of the color picture tube are incident, have a radius of curvature of 100 mm to 500 mm and a reflectance of 14% or lower.

8. The exposure device according to claim 6,
wherein the main lens has a refractive index of 1.4 to 1.6.

9. The exposure device according to claim 6,
wherein the incidence surface of the main lens is a non-spherical surface.
